(19) United States
(12) Patent Application Publication
(10) Pub. No.: US 2009/0028745 A1
(43) Pub. Date: Jan. 29, 2009

(54) RUTHENIUM PRECURSOR WITH TWO DIFFERING LIGANDS FOR USE IN SEMICONDUCTOR APPLICATIONS

(76) Inventors: Julien Gatineau, Tsuchiura (JP); Christian Dussarrat, Wilmington, DE (US)

Correspondence Address: AIR LIQUIDE;Intellectual Property, 2700 POST OAK BOULEVARD, SUITE 1800, HOUSTON, TX, 77056, US

(21) Appl. No.: 12/179,239

(22) Filed: Jul. 24, 2008

Related U.S. Application Data
(60) Provisional application No. 60/951,651, filed on Jul. 24, 2007.

(51) Int. Cl. C22C 5/04; H01L 21/31

(52) U.S. Cl. 420/462; 438/778; 257/E21.249

(57) ABSTRACT

Methods of forming a ruthenium containing film on a substrate with a ruthenium precursor which contains nitrogen and two differing ligands.

### CROSS REFERENCE TO RELATED APPLICATIONS

The present application claims the benefit of U.S. Provisional Application Ser. No. 60/951,651, filed Jul. 24, 2007, herein incorporated by reference in its entirety for all purposes.

### BACKGROUND

1. Field of the Invention

This invention relates generally to the field of semiconductor fabrication. More specifically, the invention relates to methods for depositing ruthenium containing films onto substrates.

2. Background of the Invention

Ruthenium (Ru) is expected to be used in semiconductor manufacturing process for many future applications. Generally speaking, the introduction of new materials to replace silicon in semiconductor devices is necessary to solve issues generated by the continuous scaling trend in the semiconductor manufacturing industry. For the next generation of devices, ruthenium is considered as the best candidate for electrode capacitors in FeRAM and DRAM applications, and its potential use in MRAM applications is also possible. Ruthenium has physical properties, such as a high melting point, a low resistivity, a high oxidation resistance, and adequate work functions, which make it a potential gate electrode material for CMOS transistors. In fact, the resistivity of ruthenium is lower than the resistivity of iridium (Ir) and of platinum (Pt), and therefore it is easier to use in dry etching process. Additionally, ruthenium oxide (RuO₂), has a high conductivity and can be formed through the diffusion of oxygen which could come from ferroelectric films such as lead-zirconate-titanate (PZT), strontium bismuth tantalate (SBT), or bismuth lanthanum titanate (BLT), thereby creating less impact on electrical properties than other metal oxides known to be more insulating. Other ruthenium based materials, such as strontium ruthenium oxide (SRO, SrRuO₃), are also being considered for use in the next generation chips.

Another promising application for ruthenium is in “Back End Of Line” (BEOL) process, where it is considered a candidate as a seed layer material for copper. The depositions of a ruthenium film on a Tantalum based material (e.g. TaN, used as an oxygen barrier layer) in CVD or ALD mode enables the direct deposit of copper without using an extensive preparation process.

Several ruthenium precursors are known and have been studied in CVD (chemical vapor deposition) or ALD (Atomic Layer Deposition) deposition mode. However, the currently available precursors have some drawbacks.

Some ruthenium precursors have a low vapor pressure (i.e. 0.25 Torr at 85° C. for Ru(EtCp)₂) and high impurity contents. Some ruthenium films have a poor adherence, some are not uniform and some may also have a characteristically long incubation time (where the incubation time is defined as the time required for the deposition to effectively start, i.e. by the difference time between the moment when the gas is flown in the reaction furnace and the moment when the film grows).

Some ruthenium precursors are not liquid and therefore need to be dissolved in a solvent to allow an easy delivery of the vapors to the reaction chamber. However, the use of a solvent may increase the impurity content in the ruthenium films. Moreover, the solvents that are used are usually toxic and/or flammable and their usage brings many constraints (e.g. safety aspects, environmental issues). Further, the use of precursors with melting points higher than 25° C. implies many additional constraints for the deposition process (e.g. heating of the delivery lines to avoid condensation of the precursor at undesired locations) and during the transportation.

Some ruthenium precursors also need to react with oxygen, and as oxygen may oxidize metal-nitride sub-layers, this could cause the metal nitride sub-layer to then lose its original properties, or cause difficulties when the substrate is an oxygen sensitive nitride based material (e.g. TaN, TiN).

Ruthenium precursors containing nitrogen are less common for use in semiconductor manufacturing. One type of nitrogen containing ruthenium precursor utilize allyl like N—C—N amidinate ligands (AMD) as shown below:

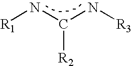

Generally these molecules have a generic formula (L)₂M(L′)₂, where L is an amidinate, and L′ a heteroatom. One type of N-containing ligand is like a β-diketiminate where the two O are replaced by N, the molecule being optionally coupled with some neutral ligands (usually O-containing). However these types of precursors have a melting point which is usually very high. The delivery of these precursors to the deposition system is therefore difficult and raises integration issues. Some of the precursors are polymeric with low vapor pressure, which requires additional resources for the delivery of sufficient quantity of precursors to the deposition system. Some precursors contain oxygen atoms which are not desired when the substrates are oxygen sensitive nitride-based materials (TaN, TiN).

Consequently, there exists a need for ruthenium compounds for use in semiconductor manufacturing processes.

### BRIEF SUMMARY

Methods and precursors for depositing a ruthenium containing film are described herein. In one embodiment, a method for depositing a ruthenium containing film on to one or more substrates comprises introducing a ruthenium precursor into a reaction chamber containing one or more substrates. The ruthenium precursor has the general formula:

LRuX₂

wherein:
L is a cyclic or acyclic unsaturated hydrocarbon η4-diene-type ligand, where L may be substituted or unsubstituted by at least one substitution group selected from: a linear or branched C1-C6 alkyl group, substituted or unsubstituted by at least one fluoro, hydroxy or amino radical; a linear or branched C1-C6 alkylamide group; a linear or branched C1-C6 alkoxy group; a linear or branched C1-C6 alkyl amidinate group; and a trialkylsylil-type group; or
L is a cyclic or acyclic C5-C10 conjugated alkadienyl hydrocarbon ligand, where L may be substituted or unsubstituted by at least one substitution group selected from: a linear or branched C1-C6 alkyl group, substituted or unsubstituted by at least one fluoro, hydroxy or amino radical; a linear or branched C1-C6 alkylamide group; a linear or branched C1-C6 alkoxy group; and a linear or branched C1-C6 alkyl amidinate group; and
X is an amidinate-type ligand, of the general formula R₁—NCR₂N—R₃, where each R is the same or different and each represents at least one substitution group selected from: hydrogen; a linear or branched C1-C6 alkyl group; a linear or branched C1-C6 perfluorocarbon group; an amino based group; a linear or branched C1-C6 alkoxy group; a linear or branched C1-C6 alkyl amidinate; and a trialkylsylil-type group.

The ruthenium precursor is then deposited to form a ruthenium containing film on the substrate or substrates in the reaction chamber.

Other embodiments of the invention may include, without limitation, one or more of the following features:
the L ligand is a cyclic or acyclic unsaturated hydrocarbon η4-diene-type ligand selected from the group consisting of: butadiene, cyclopentadiene, pentadiene, hexadiene, cyclohexadiene, norbornadiene (bi-cycloheptadiene), cycloheptadiene, heptadiene, cyclooctadiene, octadiene, and carbine;
the X ligand is an amidinate-type ligand, of the general formula R₁—NCR₂N—R₃, where each R is the same or different and each represents at least one substitution group selected from; a linear or branched C1-C6 alkyl group, substituted or unsubstituted by at least one fluoro, hydroxy or amino radical; a linear or branched C1-C6 alkoxy group; and a linear or branched C1-C6 alkyl amidinate;
the X and L ligands are substituted or unsubstituted by at least one of a linear or branched C1-C6 alkyl group, substituted or unsubstituted by at least one fluoro, or amino radical.
the X and L ligands are substituted or unsubstituted by at least one of a linear or branched methyl, ethyl, propyl or butyl group;
the L ligand is selected from one of: 1,3-cyclohexadiene, 1,4-cyclohexadiene, 1-Methyl-1,4-cyclohexadiene, 3-Methyl-1,4-cyclohexadiene, 1-Methyl-1,3-cyclohexadiene, 2-Methyl-1,3-cyclohexadiene, 5-Methyl-1,3-cyclohexadiene, 1-Ethyl-1,4-cyclohexadiene, 3-Ethyl-1,4-cyclohexadiene, 1-Ethyl-1,3-cyclohexadiene, 2-Ethyl-1,3-cyclohexadiene, 5-Ethyl-1,3-cyclohexadiene, 1,3-hexadiene, 1-methyl-1,3-hexadiene, 2-methyl-1,3-hexadiene, 3-methyl-1,3-hexadiene, 4-methyl-1,3-hexadiene, 5-methyl-1,3-hexadiene, 6-methyl-1,3-hexadiene, 1-ethyl-1,3-hexadiene, 2-ethyl-1,3-hexadiene, 3-ethyl-1,3-hexadiene, 4-ethyl-1,3-hexadiene, 5-ethyl-1,3-hexadiene, 6-ethyl-1,3-hexadiene, 1-propyl-1,3-hexadiene, 2-propyl-1,3-hexadiene, 3-propyl-1,3-hexadiene, 4-propyl-1,3-hexadiene, 5-propyl-1,3-hexadiene, 6-propyl-1,3-hexadiene, 1-butyl-1,3-hexadiene, 2-butyl-1,3-hexadiene, 3-butyl-1,3-hexadiene, 4-butyl-1,3-hexadiene, 5-butyl-1,3-hexadiene, 6-butyl-1,3-hexadiene, 1,4-hexadiene, 1-methyl-1,4-hexadiene, 2-methyl-1,4-hexadiene, 3-methyl-1,4-hexadiene, 4-methyl-1,4-hexadiene, 5-methyl-1,4-hexadiene, 6-methyl-1,4-hexadiene, 1-ethyl-1,4-hexadiene, 2-ethyl-1,4-hexadiene, 3-ethyl-1,4-hexadiene, 4-ethyl-1,4-hexadiene, 5-ethyl-1,4-hexadiene, 6-ethyl-1,4-hexadiene, 1-propyl-1,4-hexadiene, 2-propyl-1,4-hexadiene, 3-propyl-1,4-hexadiene, 4-propyl-1,4-hexadiene, 5-propyl-1,4-hexadiene, 6-propyl-1,4-hexadiene, 1-butyl-1,4-hexadiene, 2-butyl-1,4-hexadiene, 3-butyl-1,4-hexadiene, 4-butyl-1,4-hexadiene, 5-butyl-1,4-hexadiene, 6-butyl-1,4-hexadiene, 1,5-hexadiene, 1-methyl-1,5-hexadiene, 2-methyl-1,5-hexadiene, 3-methyl-1,5-hexadiene, 1-ethyl-1,5-hexadiene, 2-ethyl-1,5-hexadiene, 3-ethyl-1,5-hexadiene, 1-propyl-1,5-hexadiene, 2-propyl-1,5-hexadiene, 3-propyl-1,5-hexadiene, 1-butyl-1,5-hexadiene, 2-butyl-1,5-hexadiene, 3-butyl-1,5-hexadiene, 2,4-hexadiene, 1-methyl-2,4-hexadiene, 2-methyl-2,4-hexadiene, 3-methyl-2,4-hexadiene, 1-ethyl-2,4-hexadiene, 2-ethyl-2,4-hexadiene, 3-ethyl-2,4-hexadiene, 1-propyl-2,4-hexadiene, 2-propyl-2,4-hexadiene, 3-propyl-2,4-hexadiene, 1-butyl-2,4-hexadiene, 2-butyl-2,4-hexadiene, 3-butyl-2,4-hexadiene, 1,3-cyclopentadiene, 1-methyl-1,3-cyclopentadiene, 2-methyl-1,3-cyclopentadiene, 5-methyl-1,3-cyclopentadiene, 1-ethyl-1,3-cyclopentadiene, 2-ethyl-1,3-cyclopentadiene, 5-ethyl-1,3-cyclopentadiene, 1-propyl-1,3-cyclopentadiene, 2-propyl-1,3-cyclopentadiene, 5-propyl-1,3-cyclopentadiene, 1-butyl-1,3-cyclopentadiene, 2-butyl-1,3-cyclopentadiene, 5-butyl-1,3-cyclopentadiene, 1,3-pentadiene, 1-methyl-1,3-pentadiene, 2-methyl-1,3-pentadiene, 3-methyl-1,3-pentadiene, 4-methyl-1,3-pentadiene, 5-methyl-1,3-pentadiene, 1-ethyl-1,3-pentadiene, 2-ethyl-1,3-pentadiene, 3-ethyl-1,3-pentadiene, 4-ethyl-1,3-pentadiene, 5-ethyl-1,3-pentadiene, 1-propyl-1,3-pentadiene, 2-propyl-1,3-pentadiene, 3-propyl-1,3-pentadiene, 4-propyl-1,3-pentadiene, 5-propyl-1,3-pentadiene, 1-butyl-1,3-pentadiene, 2-butyl-1,3-pentadiene, 3-butyl-1,3-pentadiene, 4-butyl-1,3-pentadiene, 5-butyl-1,3-pentadiene,1,4-pentadiene, 1-methyl-1,4-pentadiene, 2-methyl-1,4-pentadiene, 3-methyl-1,4-pentadiene, 1-ethyl-1,4-pentadiene, 2-ethyl-1,4-pentadiene, 3-ethyl-1,4-pentadiene, 1-propyl-1,4-pentadiene, 2-propyl-1,4-pentadiene, 3-propyl-1,4-pentadiene, 1-butyl-1,4-pentadiene, 2-butyl-1,4-pentadiene, 3-butyl-1,4-pentadiene, 1,3-butadiene, 1-methyl-1,3-butadiene, 2-methyl-1,3-butadiene, 1-ethyl-1,3-butadiene, 2-ethyl-1,3-butadiene, 1-propyl-1,3-butadiene, 2-propyl-1,3-butadiene, 1-butyl-1,3-butadiene, and 2-butyl-1,3-butadiene, where the propyl and butyl ligands described can be in any possible configuration (e.g. sec, iso, tert . . . );
X is selected from one of: amidinate (R₁═R₂═R₃═H), 1-methyl-amidinate, 2-methylamidinate, 1-ethylamidinate, 2-ethyl-amidinate, 1-propyl-amidinate, 2-propyl-amidinate, 1-butyl-amidinate, 2-butyl-amidinate, N,2-dimethyl-amidinate, N,N′-dimethyl-amidinate, N,N′,2-trimethylamidinate, N,2-diethyl-amidinate, N,N′-diethyl-amidinate, N,N′,2-triethylamidinate, N,2-dipropyl-amidinate, N,N′-dipropyl-amidinate, N,N′,2-tripropylamidinate, N,2-dibutyl-amidinate, N,N′-dibutyl-amidinate, N,N′,2-tributylamidinate, 2-methyl-N,N′-diethyl-amidinate, 2-methyl-N,N′-dipropyl-amidinate, 2-methyl-N,N′-dibutyl-amidinate, 2-ethyl-N,N′-dipropyl-amidinate, 2-ethyl-N,N′-dibutyl-amidinate, 2-propyl-N,N′-diethyl-amidinate, 2-propyl-N,N′-dibutyl-amidinate, 2-butyl-N,N′-diethyl-amidinate, and 2-butyl-N,N′-dipropyl-amidinate where the propyl and butyl ligands described can be in any possible configuration (e.g. sec, iso, tert . . . );
the ruthenium precursor is Bis(2-methyl-N,N′-diisopropylamidinate)(1,4-cyclohexadiene)ruthenium;
the ruthenium precursor is deposited at a temperature between about 100 C and about 500 C, preferably between about 150 C and about 350 C;
a reducing fluid is introduced into the reaction chamber, either separately from or together with the ruthenium precursor;
the reducing fluid is selected from H₂, NH₃, SiH₄, Si₂H₆, Si₃H₈; and mixtures thereof;
an oxygen-containing fluid is introduced into the reaction chamber, either separately from or together with the ruthenium precursor; and
the oxygen-containing fluid is selected from O₂, O₃, H₂O, H₂O₂, oxygen-containing radicals such as O° and OH°.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### DETAILED DESCRIPTION OF EMBODIMENTS

In one embodiment, a method for depositing a ruthenium containing film comprises introducing, into a reaction chamber containing one or more substrates, an organo-metallic ruthenium precursor of the general formula:

LRuX₂

In some embodiments, L is an unsaturated hydrocarbon η4-diene-type ligand cyclic or acyclic, which may be selected from butadiene, cyclopentadiene, pentadiene, hexadiene, cyclohexadiene, norbornadiene (bi-cycloheptadiene), cycloheptadiene, heptadiene, cyclooctadiene, octadiene, carbine. The ligand L may be unsubstituted or substituted by one or more substitution groups selected from: linear or branched alkyl groups having from one to six carbon atoms, unsusbstituted or substituted by one or more radicals selected from fluoro, hydroxy or amino; linear or branched alkylamide groups having from one to six carbon atoms; linear or branched alkoxy groups having from one to six carbon atoms; linear or branched alkyl amidinates having from one to six carbon atoms; and trialkylsyllil-type groups. In some embodiments and when applicable, the alkyls may be independently chosen among linear or branched methyl, ethyl, propyl, and butyl.

In some embodiments, X is an amidinate-type (AMD) ligand of the general formula R₁—NCR₂N—R₃, where each of R₁, R₂, R₃ is a substitution group. Each R may be independently selected from; hydrogen; linear or branched alkyl groups having from one to six carbon atoms; linear or branched perfluorocarbon groups having from one to six carbon atoms; amino-based groups; linear or branched alkoxy groups having from one to six carbon atoms; or trialkylsilyl-type groups. In some embodiments and when applicable, the alkyls may be independently chosen among linear or branched methyl, ethyl, propyl, and butyl. In some embodiments the AMD ligand X may be selected from: diisopropylamidinate (R1=R3=isopropyl; R′═H); dibutylamidinate (R1=R2=butyl; R′═H); methyidiisopropyalamidinate (R1=R3=isopropyl; R2=methyl); and methyldibutylamidinate (R1=R3=butyl; R2=methyl).

In some embodiments, the organo-metallic ruthenium compounds have low melting points. Preferably, these precursors are liquid at room temperature. As a consequence, these precursors may be provided to the semiconductor manufacturing process as substantially pure liquids, without the addition of a solvent, thereby enabling the deposition of substantially pure ruthenium films or ruthenium containing films (depending on the co-reactant used with the precursor). This also allows an ALD deposition regime for pure ruthenium deposition as well as for deposition of other ruthenium containing films (SrRuO₃, RuO₂ for example).

In some embodiments of the organo-metallic ruthenium compounds described above, the molecule is asymmetric, which is believed to help increase planar disorder of the molecule, decrease Van der Walls forces of the molecules and thereby help obtain low melting points molecules with high volatility. In some embodiments, these molecules contain 2 types of ligands, each independently allowing the deposition of pure ruthenium films in ALD mode using hydrogen instead of oxygen. These molecules are stable in air and towards moisture.

In some embodiments, the ligand L may be the six carbon closed ring 1,4-cyclohexadiene, which has two carbon-carbon double bonds (shown below in face and profile):

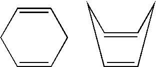

In some embodiments, the ligand L may have configurations with the double bonds in different places, such as 1,3-cylcohexadiene (shown below in face and profile):

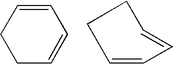

In some embodiments, the ligand L may be substituted with an alkyl group. For instance, the ligand L may be 1-methyl-1-4cyclohexadiene (as shown below in face and profile):

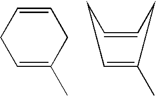

In some embodiments where the L ligand is substituted, suitable substitution groups may be selected from: hydrogen; halides (F, Cl, I, Br); linear or branched alkyl groups having from one to six carbon atoms, unsubstituted or substituted by one or more groups selected from fluoro, or amino; linear or branched alkylamides group having from one to six carbon atoms; linear or branched alkoxy groups having from one to six carbon atoms.

In one embodiment, the ruthenium precursor may be Bis(2-Methyl-N,N′-diisopropylamidinate)(1,4-cyclohexadiene)ruthenium, shown structurally below:

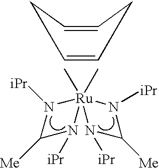

A ruthenium precursor, according to some embodiments described herein, may be synthesized in the following manner:
1—Ruthenium(II) complex (η4-cyclohexadiene)Ru(pyridine)2Cl2 and Li[iPrNC(Me)=NiPr] may be synthesized in a conventional manner;
2—In a Schlenk tube, (η4-cyclohexadiene)Ru(pyridine)2Cl2 is treated with Li[iPrNC(Me)=NiPr] in THF at room temperature for about 24 hours;
3—The solvent is removed in vacuo and the residue is absorbed to celite;
4—The absorbed material is moved to the head of an alumina column and eluted with a mixture of hexane and Et2O (10:1)
5—The desired product is obtained in good yield (around 70% or higher).

The disclosed ruthenium precursor compounds may used in semiconductor manufacturing processes, via deposition on substrates, through various deposition methods. Examples of suitable deposition methods include, without limitation, chemical vapor deposition (CVD), atomic layer deposition, and pulsed chemical vapor deposition (PCVD).

In some embodiments, a reaction chamber contains at least one substrate, and a ruthenium precursor is introduced into the reaction chamber. The reaction chamber (or reactor) may be any enclosure or chamber within a device in which deposition methods take place, such as, without limitation, a cold-wall type reactor, a hot-wall type reactor, a single-wafer reactor, a multi-wafer reactor, or other such types of deposition systems.

The type of substrate upon which the precursor will be deposited may vary. In some embodiments, the substrate may be chosen from oxides which are used as dielectric materials in MIM, DRAM, FeRAM technologies or gate dielectrics in CMOS technologies (for instance: HfO based materials, TiO2 based materials, ZrO2 based materials, rare earth oxide based materials, ternary oxide based materials, etc. . . . ) or from nitride-based films (TaN for instance) that are used as a oxygen barrier layer between copper and the low-k layer.

In some embodiments, a ruthenium containing film may be formed on the substrate through a decomposition or adsorption of the precursor onto the substrate. In some embodiments, at least one reducing fluid is introduced into the reaction chamber. In some embodiments, an oxygen-containing fluid is introduced into the reaction chamber. In some embodiments, the reducing fluid may be selected from H2, NH₃, SiH₄, Si₂H₆, Si₃H₈, hydrogen containing fluids and mixtures thereof. In some embodiments, the oxygen-containing fluid may be selected from O₂, O₃, H₂O, H₂O₂, oxygen-containing radicals such as O° or OH°, or mixtures thereof.

In some embodiments, the various reactants may be introduced to the reaction chamber simultaneously (e.g. CVD), while in other embodiments the various reactants may be introduced to the reaction chamber sequentially (e.g. ALD); or still in other embodiments the various reactants may be introduced through a series of pulses (e.g. PCVD).

In some embodiments, an inert gas (e.g. N₂, Ar, He) may be introduced into the reaction chamber to purge the reaction chamber between the introductions of reactants. For instance, the reaction chamber may be purged with an inert gas to remove residual precursor before the introduction of the reducing, or oxygen-containing fluids. Likewise, the reaction chamber may be purged with an inert gas to remove residual reducing, or oxygen-containing fluid before the introduction (or reintroduction) of the precursor.

For example, in some embodiments, the reducing fluid and/or oxygen-containing fluid as well as the ruthenium precursor may be sequentially introduced into the reaction chamber, separated by purge of the reaction chamber by inert gas. The deposition is made by successively introducing vapors of the ruthenium precursor during a certain time when the precursor uniformly adsorbs on the substrate (1^{st} step), followed by an inert purge gas (2^{nd} step), followed by the introduction of the co-reactant (e.g. reducing fluid or oxygen-containing fluid) that is going to react with the previously deposited ruthenium-based layer (3^{rd} step), followed by a second purge by inert gas (4^{th} step). Such a 4 step process is called a cycle and ideally enables the deposition of one uniform ruthenium-based layer. Broadly, this deposition technique is called Atomic Layer Deposition (ALD).

In some embodiments, the ruthenium precursor is a liquid, with a melting point below 25° C. and preferably with a melting point below 0° C. In some embodiments, the process conditions within the reaction chamber are such that the temperature is between about 100° C. and about 500° C., and preferably between about 150° C. and about 350° C. In some embodiments, the pressure in the reaction chamber is maintained between about 1 Pa and about 10⁵ Pa, and preferably between about 25 Pa and about 10³ Pa.

### EXAMPLES

The following non-limiting examples are provided to further illustrate embodiments of the invention. However, the examples are not intended to be all inclusive and are not intended to limit the scope of the inventions described herein.

### Deposition of Pure Ruthenium Films:

Pure ruthenium films were deposited at temperatures above 250° C. using Bis(2-Methyl-N,N′-diisopropylamidinate)(1,4-cyclohexadiene)ruthenium. The liquid precursor was stored in a bubbler and its vapors were delivered to the hot-wall reaction chamber by a bubbling method. An inert gas, (e.g. helium, nitrogen), was used as a carrier gas, as well as for dilution purpose. Tests were done with and without hydrogen as co-reactant.

Under these conditions, films were deposited from 250° C., at 0.5 Torr, and the deposition rate reached a plateau at 350° C. Depositions were done on thermal silicon oxide as well as on other dielectric materials. The concentration of various elements into the ruthenium films were analyzed by an Auger spectrometer and pure ruthenium films were obtained. The concentration of oxygen in the ruthenium film was below the detection limit of AES.

### Atomic Layer Deposition:

The ruthenium precursor Bis(2-Methyl-N,N′-diisopropylamidinate)(1,4-cyclohexadiene)ruthenium is suitable for the atomic layer deposition (ALD) of ruthenium films at low temperatures (150-350° C.) using the appropriate co-reactant. It has been found that metallic ruthenium depositions in ALD technique are possible when the co-reactant is molecular and atomic hydrogen, as well as with ammonia and related radicals NH₂, NH, and oxidants.

### Deposition of Ruthenium Oxide Films:

Ruthenium oxide films were deposited by reacting Bis(2-Methyl-N,N′-diisopropylamidinate)(1,4-cyclohexadiene)ruthenium with an oxygen-containing fluid in a deposition furnace. In this particular case, the oxygen-containing fluid was oxygen. It has been found that ruthenium oxide depositions in ALD technique are possible when the co-reactant is molecular and atomic oxygen, as well as moisture vapors or any other oxygen-containing mixture.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for depositing a ruthenium containing film on to one or more substrates comprising:
a) introducing a ruthenium precursor into a reaction chamber containing one or more substrates, wherein the ruthenium precursor comprises a compound having the formula:
LRuX₂
wherein:
L is a cyclic or acyclic unsaturated hydrocarbon η4-diene-type ligand, where L may be substituted or unsubstituted by at least one substitution group selected from: a linear or branched C1-C6 alkyl group, substituted or unsubstituted by at least one fluoro, hydroxy or amino radical; a linear or branched C1-C6 alkylamide group; a linear or branched C1-C6 alkoxy group; a linear or branched C1-C6 alkyl amidinate group; and a trialkylsylil-type group; or
L is a cyclic or acyclic C5-C10 conjugated alkadienyl hydrocarbon ligand, where L may be substituted or unsubstituted by at least one substitution group selected from: a linear or branched C1-C6 alkyl group, substituted or unsubstituted by at least one fluoro, hydroxy or amino radical; a linear or branched C1-C6 alkylamide group; a linear or branched C1-C6 alkoxy group; and a linear or branched C1-C6 alkyl amidinate group; and
X is an amidinate-type ligand, of the general formula R₁-NCR₂N—R₃, where each R is the same or different and each represents at least one substitution group selected from: hydrogen; a linear or branched C1-C6 alkyl group; a linear or branched C1-C6 perfluorocarbon group; an amino based group; a linear or branched C1-C6 alkoxy group; a linear or branched C1-C6 alkyl amidinate; and a trialkylsylil-type group; and
b) depositing the ruthenium precursor to form a ruthenium film on the one or more substrates.

2. The method of claim 1, wherein L comprises a cyclic or acyclic unsaturated hydrocarbon η4-diene-type ligand selected from the group consisting of: butadiene, cyclopentadiene, pentadiene, hexadiene, cyclohexadiene, norbornadiene (bi-cycloheptadiene), cycloheptadiene, heptadiene, cyclooctadiene, octadiene, and carbine.

3. The method of claim 1, wherein X further comprises an amidinate-type ligand, of the general formula R₁—NCR₂N—R₃, where each R is the same or different and each represents at least one substitution group selected from; a linear or branched C1-C6 alkyl group, substituted or unsubstituted by at least one fluoro, hydroxy or amino radical; a linear or branched C1-C6 alkoxy group; and a linear or branched C1-C6 alkyl amidinate.

4. The method of claim 1, wherein X and L are substituted or unsubstituted by at least one a linear or branched C1-C6 alkyl group, substituted or unsubstituted by at least one fluoro, or amino radical.

5. The method of claim 1, wherein X and L are substituted or unsubstituted by at least one linear or branched substation group selected from the group consisting of methyl, ethyl, propyl and butyl.

6. The method of claim 1, wherein L comprises at least one member selected from the group consisting of: 1,3-cyclohexadiene, 1,4-cyclohexadiene, 1-Methyl-1,4-cyclohexadiene, 3-Methyl-1,4-cyclohexadiene, 1-Methyl-1,3-cyclohexadiene, 2-Methyl-1,3-cyclohexadiene, 5-Methyl-1,3-cyclohexadiene, 1-Ethyl-1,4-cyclohexadiene, 3-Ethyl-1,4-cyclohexadiene, 1-Ethyl-1,3-cyclohexadiene, 2-Ethyl-1,3-cyclohexadiene, 5-Ethyl-1,3-cyclohexadiene, 1,3-hexadiene, 1-methyl-1,3-hexadiene, 2-methyl-1,3-hexadiene, 3-methyl-1,3-hexadiene, 4-methyl-1,3-hexadiene, 5-methyl-1,3-hexadiene, 6-methyl-1,3-hexadiene, 1-ethyl-1,3-hexadiene, 2-ethyl-1,3-hexadiene, 3-ethyl-1,3-hexadiene, 4-ethyl-1,3-hexadiene, 5-ethyl-1,3-hexadiene, 6-ethyl-1,3-hexadiene, 1-propyl-1,3-hexadiene, 2-propyl-1,3-hexadiene, 3-propyl-1,3-hexadiene, 4-propyl-1,3-hexadiene, 5-propyl-1,3-hexadiene, 6-propyl-1,3-hexadiene, 1-butyl-1,3-hexadiene, 2-butyl-1,3-hexadiene, 3-butyl-1,3-hexadiene, 4-butyl-1,3-hexadiene, 5-butyl-1,3-hexadiene, 6-butyl-1,3-hexadiene, 1,4-hexadiene, 1-methyl-1,4-hexadiene, 2-methyl-1,4-hexadiene, 3-methyl-1,4-hexadiene, 4-methyl-1,4-hexadiene, 5-methyl-1,4-hexadiene, 6-methyl-1,4-hexadiene, 1-ethyl-1,4-hexadiene, 2-ethyl-1,4-hexadiene, 3-ethyl-1,4-hexadiene, 4-ethyl-1,4-hexadiene, 5-ethyl-1,4-hexadiene, 6-ethyl-1,4-hexadiene, 1-propyl-1,4-hexadiene, 2-propyl-1,4-hexadiene, 3-propyl-1,4-hexadiene, 4-propyl-1,4-hexadiene, 5-propyl-1,4-hexadiene, 6-propyl-1,4-hexadiene, 1-butyl-1,4-hexadiene, 2-butyl-1,4-hexadiene, 3-butyl-1,4-hexadiene, 4-butyl-1,4-hexadiene, 5-butyl-1,4-hexadiene, 6-butyl-1,4-hexadiene, 1,5-hexadiene, 1-methyl-1,5-hexadiene, 2-methyl-1,5-hexadiene, 3-methyl-1,5-hexadiene, 1-ethyl-1,5-hexadiene, 2-ethyl-1,5-hexadiene, 3-ethyl-1,5-hexadiene, 1-propyl-1,5-hexadiene, 2-propyl-1,5-hexadiene, 3-propyl-1,5-hexadiene, 1-butyl-1,5-hexadiene, 2-butyl-1,5-hexadiene, 3-butyl-1,5-hexadiene, 2,4-hexadiene, 1-methyl-2,4-hexadiene, 2-methyl-2,4-hexadiene, 3-methyl-2,4-hexadiene, 1-ethyl-2,4-hexadiene, 2-ethyl-2,4-hexadiene, 3-ethyl-2,4-hexadiene, 1-propyl-2,4-hexadiene, 2-propyl-2,4-hexadiene, 3-propyl-2,4-hexadiene, 1-butyl-2,4-hexadiene, 2-butyl-2,4-hexadiene, 3-butyl-2,4-hexadiene, 1,3-cyclopentadiene, 1-methyl-1,3-cyclopentadiene, 2-methyl-1,3-cyclopentadiene, 5-methyl-1,3-cyclopentadiene, 1-ethyl-1,3-cyclopentadiene, 2-ethyl-1,3-cyclopentadiene, 5-ethyl-1,3-cyclopentadiene, 1-propyl-1,3-cyclopentadiene, 2-propyl-1,3-cyclopentadiene, 5-propyl-1,3-cyclopentadiene, 1-butyl-1,3-cyclopentadiene, 2-butyl-1,3-cyclopentadiene, 5-butyl-1,3-cyclopentadiene, 1,3-pentadiene, 1-methyl-1,3-pentadiene, 2-methyl-1,3-pentadiene, 3-methyl-1,3-pentadiene, 4-methyl-1,3-pentadiene, 5-methyl-1,3-pentadiene, 1-ethyl-1,3-pentadiene, 2-ethyl-1,3-pentadiene, 3-ethyl-1,3-pentadiene, 4-ethyl-1,3-pentadiene, 5-ethyl-1,3-pentadiene, 1-propyl-1,3-pentadiene, 2-propyl-1,3-pentadiene, 3-propyl-1,3-pentadiene, 4-propyl-1,3-pentadiene, 5-propyl-1,3-pentadiene, 1-butyl-1,3-pentadiene, 2-butyl-1,3-pentadiene, 3-butyl-1,3-pentadiene, 4-butyl-1,3-pentadiene, 5-butyl-1,3-pentadiene, 1,4-pentadiene, 1-methyl-1,4-pentadiene, 2-methyl-1,4-pentadiene, 3-methyl-1,4-pentadiene, 1-ethyl-1,4-pentadiene, 2-ethyl-1,4-pentadiene, 3-ethyl-1,4-pentadiene, 1-propyl-1,4-pentadiene, 2-propyl-1,4-pentadiene, 3-propyl-1,4-pentadiene, 1-butyl-1,4-pentadiene, 2-butyl-1,4-pentadiene, 3-butyl-1,4-pentadiene, 1,3-butadiene, 1-methyl-1,3-butadiene, 2-methyl-1,3-butadiene, 1-ethyl-1,3-butadiene, 2-ethyl-1,3-butadiene, 1-propyl-1,3-butadiene, 2-propyl-1,3-butadiene, 1-butyl-1,3-butadiene, and 2-butyl-1,3-butadiene.

7. The method of claim 1,wherein X comprises at least one member selected from the group consisting of: amidinate (R₁═R₂═R₃═H), 1-methyl-amidinate, 2-methylamidinate, 1-ethylamidinate, 2-ethyl-amidinate, 1-propyl-amidinate, 2-propyl-amidinate, 1-butyl-amidinate, 2-butyl-amidinate, N,2-dimethyl-amidinate, N,N′-dimethyl-amidinate, N,N′,2-trimethylamidinate, N,2-diethyl-amidinate, N,N′-diethyl-amidinate, N,N′,2-triethylamidinate, N,2-dipropyl-amidinate, N,N′-dipropyl-amidinate, N,N′,2-tripropylamidinate, N,2-dibutyl-amidinate, N,N′-dibutyl-amidinate, N,N′,2-tributylamidinate, 2-methyl-N,N′-diethyl-amidinate, 2-methyl-N,N′-dipropyl-amidinate, 2-methyl-N,N′-dibutyl-amidinate, 2-ethyl-N,N′-dipropyl-amidinate, 2-ethyl-N,N′-dibutyl-amidinate, 2-propyl-N,N′-diethyl-amidinate, 2-propyl-N,N′-dibutyl-amidinate, 2-butyl-N,N′-diethyl-amidinate, and 2-butyl-N,N′-dipropyl-amidinate.

8. The method of claim 1, wherein the ruthenium precursor comprises Bis(2-methyl-N,N′-diisopropylamidinate)(1,4-cyclohexadiene)ruthenium.

9. The method of claim 1, further comprising depositing the ruthenium precursor at a temperature between about 100 C and about 500 C.

10. The method of claim 9, further comprising depositing the ruthenium precursor at a temperature between about 150 C and about 350 C.

11. The method of claim 1,further comprising introducing at least one reducing fluid, either together or separately with the ruthenium precursor into the reaction chamber.

12. The method of claim 11,wherein the reducing fluid comprises at least one member selected from the group consisting of: H₂, NH₃, SiH₄, Si₂H₆, Si₃H₈; and mixtures thereof.

13. The method of claim 1, further comprising introducing at least one oxygen-containing fluid, either separately or with the ruthenium precursor, into the reaction chamber.

14. The method of claim 13, wherein the oxygen-containing fluid comprises at least one member selected from the group consisting of: O₂, O₃, H₂O, H₂O₂, oxygen-containing radicals such as O° and OH°, and mixtures thereof.

15. A method for depositing a ruthenium containing film on to one or more substrates comprising:
a) introducing a ruthenium precursor into a reaction chamber containing one or more substrate, wherein the ruthenium precursor comprises a compound having the formula:
LRuX₂
wherein:
L is a cyclic or acyclic unsaturated hydrocarbon η4-diene-type ligand, where L may be substituted or unsubstituted by at least one substitution group selected from: a linear or branched C1-C6 alkyl group, substituted or unsubstituted by at least one fluoro, hydroxy or amino radical; a linear or branched C1-C6 alkylamide group; a linear or branched C1-C6 alkoxy group; a linear or branched C1-C6 alkyl amidinate group; and a trialkylsylil-type group;
X is an amidinate-type ligand, of the general formula R₁—NCR₂N—R₃, where each R is the same or different and each represents at least one substitution group selected from: hydrogen; a linear or branched C1-C6 alkyl group; a linear or branched C1-C6 perfluorocarbon group; an amino based group; a linear or branched C1-C6 alkoxy group; a linear or branched C1-C6 alkyl amidinate; and a trialkylsylil-type group; and
b) depositing the ruthenium precursor to form a ruthenium film on the one or more substrates.

16. The ruthenium containing film according to the method of claim 15, wherein the ruthenium precursor comprises Bis(2-methyl-N,N′-diisopropylamidinate)(1,4-cyclohexadiene)ruthenium.
